(19) United States
(12) Patent Application Publication
(10) Pub. No.: US 2024/0329335 A1
(43) Pub. Date: Oct. 3, 2024

(54) PHOTODIODE ASSEMBLY FOR LOW CROSS TALK

(71) Applicant: II-VI Delaware, Inc., Wilmington, DE (US)

(72) Inventors: Nick DuBuisson, Exmouth (GB); Jeffrey Greatrex, Torquay (AU); Nadhum Zayer, Devon (GB)

(21) Appl. No.: 18/127,163

(22) Filed: Mar. 28, 2023

(51) Int. Cl. G02B 6/42

(52) U.S. Cl. CPC G02B 6/4203

(57) ABSTRACT

This disclosure describes a use of cleaved optical fibre and PIN diode placement to reduce optical feedback from a plurality of PIN diodes. The PIN diodes may be separated in two or three dimensions to increase isolation.

### BACKGROUND

Limitations and disadvantages of traditional photodiodes will become apparent to one of skill in the art, through comparison of such approaches with some aspects of the present method and system set forth in the remainder of this disclosure with reference to the drawings.

### BRIEF SUMMARY

Systems and methods are provided for producing a photodiode assembly for low cross talk, substantially as illustrated by and/or described in connection with at least one of the figures, as set forth more completely in the claims.

### BRIEF DESCRIPTION OF THE DRAWINGS

FIG. 1 illustrates a first example photodiode assembly, in accordance with various example implementations of this disclosure.

FIG. 2 illustrates a second example photodiode assembly, in accordance with various example implementations of this disclosure.

FIG. 3 illustrates a third example photodiode assembly, in accordance with various example implementations of this disclosure.

FIG. 3 illustrates a third example photodiode assembly, in accordance with various example implementations of this disclosure.

FIG. 4 illustrates a fourth example photodiode assembly, in accordance with various example implementations of this disclosure.

FIG. 5 illustrates a fifth example photodiode assembly, in accordance with various example implementations of this disclosure.

### DETAILED DESCRIPTION

This disclosure describes a system comprising a plurality of photodiodes assembled in close proximity. An example use of such an assembly is for an underwater optical repeater for submarine networks. As repeaters evolve to higher and higher fiber pair counts submarine networks are faced with tighter space constraints. Furthermore, all photodiodes in a submarine application need to meet stringent isolation requirements (e.g., better than −40 dB isolation). Accordingly, such a device in a reduced package size is advantageous. The disclosed invention demonstrates that multiple photodiodes can be integrated into a single package with minimum cross talk.

The conventional way of packaging photodiodes is based on a single photodiode per package for terrestrial and submarine deployments. The photodiode may be a PIN diode, which is a type of diode having undoped intrinsic semiconductor region placed between two regions called p-type semiconductor and the n-type semiconductor region. The acronym “PIN” corresponds to the semiconductor stack of P-type, intrinsic, and N-type material. PIN diodes can be made both on Gallium Arsenide (GaAs) or silicon.

While there are suppliers offering packaged Indium Gallium Arsenide (InGaAs) photodiodes arrays in the market, these suppliers fail to offer high isolation performance (>−40 dB) required by submarine customers. There are currently no other suppliers of packaged InGaAs photodiodes to the submarine market, mainly due to the small market size.

The disclosed assembles may utilize more than one photodiode associated with a common carrier. Multiple photodiode assemblies may be separated and stacked in the optical axis direction. Fibre lengths may be defined per individual photodiode position. Fibres may be actively aligned to each photodiode for maximum responsivity.

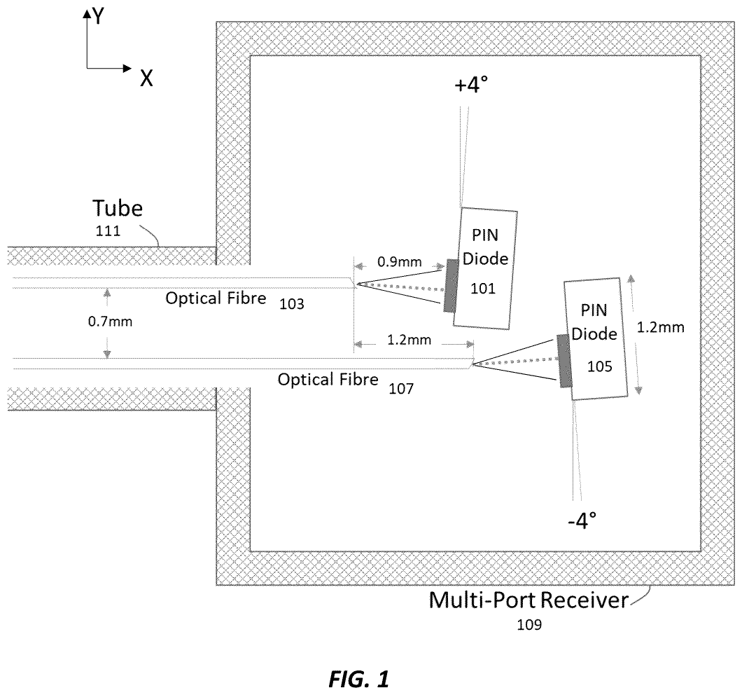

FIG. 1 illustrates a first example photodiode assembly, in accordance with various example implementations of this disclosure.

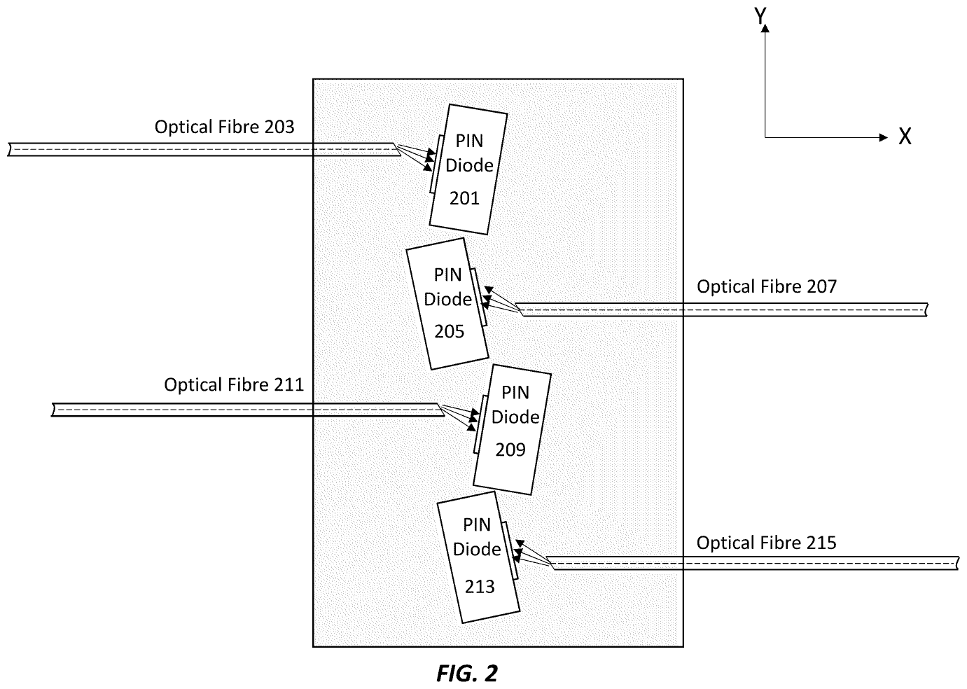

As illustrated in FIG. 1, a tube 111, comprising two optical fibres 103 and 107, is coupled to a multi-port receiver 109, comprising two PIN diodes 101 and 105. While the example pre-defined spacing between each optical fibre 103 and 107 in FIG. 1 is 0.7 mm, it should be noted that a narrower or wider spacing may be used. It should also be noted that a value, x, is approximately 0.7 mm if 0.65 mm≤x<0.75 mm. While FIG. 1 illustrates two optical fibres 103 and 107 and two PIN diodes 101 and 105, it will become evident from the description (below) of FIGS. 2, 3 and 4 that more optical fibres and two PIN diodes may be used.

The first optical fibre 103 is parallel to the second optical fibre 107. The first photo-diode 101 is coupled to the first optical fibre 103. The second photo-diode 105 is coupled to the second optical fibre 107. The first and second optical fibres 103 and 105 are each cleaved at an angle such that the first primary optical path, exiting the first optical fibre 103, is not parallel to the second primary optical path, exiting the second optical fibre 103.

The ends of each optical fibre 103 and 107 are cleaved to generate a projected angle between the axis of the associated optical fibre 103 or 107 and the principal ray (shown as dotted) of a light beam exiting the associated optical fibre 103 or 107. While the example projected angle in FIG. 1 is 4°, it should be noted that a smaller or larger projected angle may be generated according to the cleave angle. It should also be noted that a value, x, is approximately 4° if 3.5°≤x<4.5°. As a convention, this disclosure will denote a clockwise measurement from normal as a positive angle and a counterclockwise measurement from normal as a negative angle.

The ends of each optical fibre 103 and 107 are offset from each other. While the example offset in FIG. 1 is 1.2 mm, it should be noted that a smaller or larger offset may be desired according to the size of the PIN diodes 101 and 105. It should also be noted that a value, x, is approximately 1.2 mm if 1.15 mm≤x<1.25 mm.

The ends of each optical fibre 103 and 107 are spaced apart from the corresponding PIN diode 101 or 105. While the example spacing between fibre and diode in FIG. 1 is 0.9 mm, it should be noted that a smaller or larger spacing may be desired according to the size of the receiving surface of the PIN diodes 101 and 105 and the spread of the divergent rays (shown as solid lines) of the light beam exiting the associated optical fibre 103 or 107. It should also be noted that a value, x, is approximately 0.9 mm if 0.85 mm≤x<0.95 mm.

The receiving surfaces of the PIN diodes 101 and 105 are each angled according to the path of the principal ray (shown as dotted) of the light beam exiting the respective optical fibres 103 and 107. The receiving surfaces of the PIN diodes 101 and 105 are configured to receive the corresponding principal ray (shown as dotted) of the light beam at approximately 90°. It should also be noted that a value, x, is approximately 90° if 85°≤x<95°.

FIG. 2 illustrates a second example photodiode assembly, in accordance with various example implementations of this disclosure.

As illustrated in FIG. 2, four optical fibres 203, 207, 211 and 215 are coupled to four PIN diodes 201, 205, 209 and 213. While FIG. 2 illustrates four optical fibres 203, 207, 211 and 215 and four PIN diodes 201, 205, 209 and 213, three or more optical fibres paired with three or more PIN diodes may be used.

The first optical fibre 203 and the third optical fibre 211 originate from the left. The second optical fibre 207 and the fourth optical fibre 215 originate from the right. All four optical fibres 203, 207, 211 and 215 are parallel to each other.

The first and second optical fibres 203 and 207 are each cleaved at an angle such that the first primary optical path, exiting the first optical fibre 203, is not parallel to the second primary optical path, exiting the second optical fibre 207. The second and third optical fibres 207 and 211 are each cleaved at an angle such that the second primary optical path, exiting the second optical fibre 207, is not parallel to the third primary optical path, exiting the third optical fibre 211. The third and fourth optical fibres 211 and 215 are each cleaved at an angle such that the third primary optical path, exiting the third optical fibre 211, is not parallel to the fourth primary optical path, exiting the fourth optical fibre 215.

The receiving surfaces of the PIN diodes 201, 205, 209 and 213 are each angled according to the path of the principal ray of the light beam exiting the respective optical fibres 203, 207, 211 and 215.

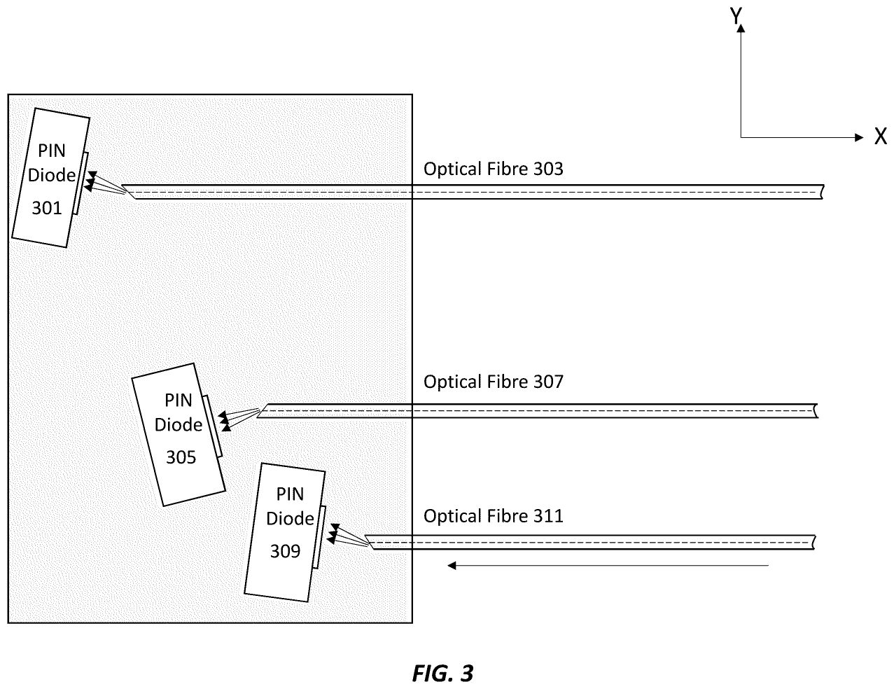

FIG. 3 illustrates a third example photodiode assembly, in accordance with various example implementations of this disclosure.

As illustrated in FIG. 3, three optical fibres 303, 307 and 311 are coupled to three PIN diodes 301, 305 and 309. All three optical fibres 303, 307 and 311 are parallel to each other. While FIG. 3 illustrates three optical fibres 303, 307 and 311 and three PIN diodes 301, 305 and 309, more than three optical fibres paired with PIN diodes may be used.

The first and second optical fibres 303 and 307 are each cleaved at an angle such that the first primary optical path, exiting the first optical fibre 303, is not parallel to the second primary optical path, exiting the second optical fibre 307. The second and third optical fibres 307 and 311 are each cleaved at an angle such that the second primary optical path, exiting the second optical fibre 307, is not parallel to the third primary optical path, exiting the third optical fibre 311.

The receiving surfaces of the PIN diodes 301, 305 and 309 are each angled according to the path of the principal ray of the light beam exiting the respective optical fibres 303, 307 and 311.

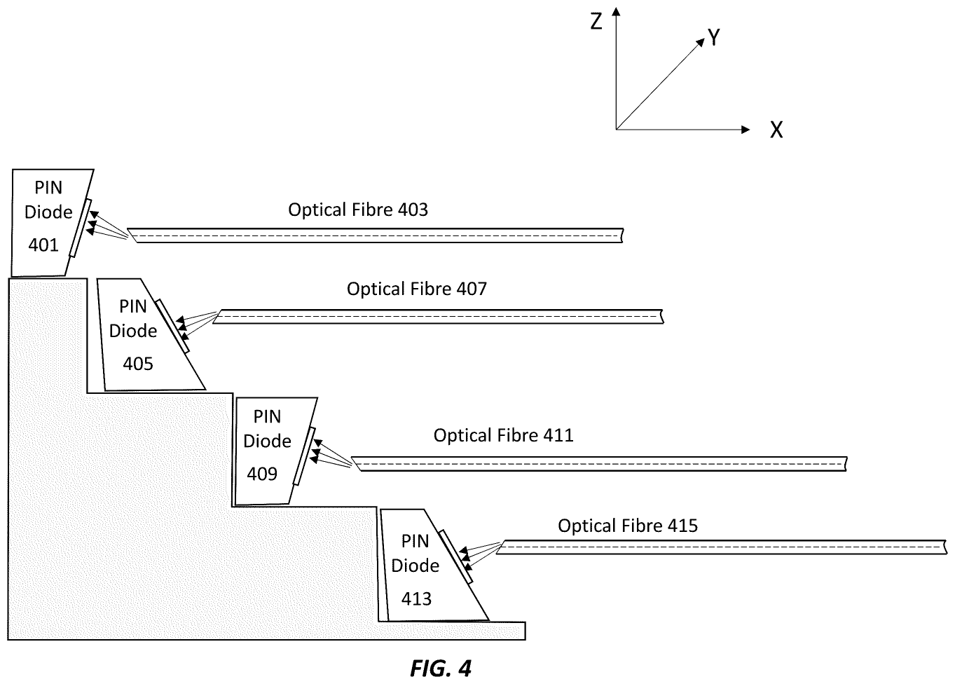

FIG. 4 illustrates a fourth example photodiode assembly, in accordance with various example implementations of this disclosure.

As illustrated in FIG. 4, four optical fibres 403, 407, 411 and 415 are coupled to four PIN diodes 401, 405, 409 and 413. While FIG. 4 illustrates four optical fibres 403, 407, 411 and 415 and four PIN diodes 401, 405, 409 and 413, three or more optical fibres paired with three or more PIN diodes may be used. All four optical fibres 403, 407, 411 and 415 are parallel to each other.

The first and second optical fibres 403 and 407 are each cleaved at an angle such that the first primary optical path, exiting the first optical fibre 403, is not parallel to the second primary optical path, exiting the second optical fibre 407. The second and third optical fibres 407 and 411 are each cleaved at an angle such that the second primary optical path, exiting the second optical fibre 407, is not parallel to the third primary optical path, exiting the third optical fibre 411. The third and fourth optical fibres 411 and 415 are each cleaved at an angle such that the third primary optical path, exiting the third optical fibre 411, is not parallel to the fourth primary optical path, exiting the fourth optical fibre 415.

The receiving surfaces of the PIN diodes 401, 405, 409 and 413 are each angled according to the path of the principal ray of the light beam exiting the respective optical fibres 403, 407, 411 and 415.

FIG. 4 differs from FIGS. 1-3 in that the four PIN diodes 401, 405, 409 and 413 in FIG. 4 are stacked via steps of a stair step arrangement. Whereby FIGS. 1-3 illustrate arrangements of PIN diodes in two dimensions (XY), FIG. 4 illustrates an arrangement of PIN diodes that adds a third dimension (Z) in the upward direction.

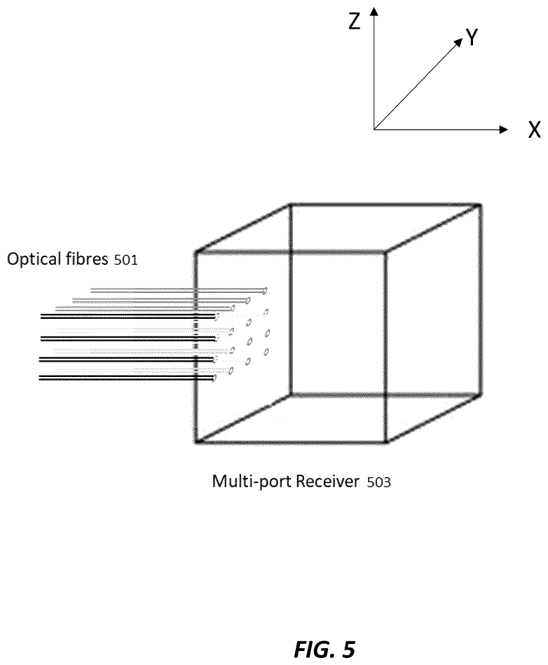

FIG. 5 illustrates a fifth example photodiode assembly, in accordance with various example implementations of this disclosure.

According to the disclosure of FIGS. 1-4, optical fibres 501 may be packed in two dimensions (YZ) as rows and columns. The PIN diodes may be positioned anywhere within the three dimensions (XYZ) of a multi-port receiver 503. The multi-port receiver 503 may be based on any three-dimensional object with any number of sides. Optical fibres 501 may enter the multiport receiver 503 from one or more sides of the multiport receiver 503. Each individual fibre of the optical fibres 501 may be angle cleaved and associated with a PIN diode that is positioned at an angle with respect to a side of the multiport receiver 503.

The present method and/or system may be realized in hardware, software, or a combination of hardware and software. The present methods and/or systems may be realized in a centralized fashion in at least one computing system, or in a distributed fashion where different elements are spread across several interconnected computing systems. Any kind of computing system or other apparatus adapted for carrying out the methods described herein is suited. A typical implementation may comprise one or more application specific integrated circuit (ASIC), one or more field programmable gate array (FPGA), and/or one or more processor (e.g., x86, x64, ARM, PIC, and/or any other suitable processor architecture) and associated supporting circuitry (e.g., storage, DRAM, FLASH, bus interface circuits, etc.). Each discrete ASIC, FPGA, Processor, or other circuit may be referred to as “chip,” and multiple such circuits may be referred to as a “chipset.” Another implementation may comprise a non-transitory machine-readable (e.g., computer readable) medium (e.g., FLASH drive, optical disk, magnetic storage disk, or the like) having stored thereon one or more lines of code that, when executed by a machine, cause the machine to perform processes as described in this disclosure. Another implementation may comprise a non-transitory machine-readable (e.g., computer readable) medium (e.g., FLASH drive, optical disk, magnetic storage disk, or the like) having stored thereon one or more lines of code that, when executed by a machine, cause the machine to be configured (e.g., to load software and/or firmware into its circuits) to operate as a system described in this disclosure.

As used herein the terms “circuits” and “circuitry” refer to physical electronic components (i.e. hardware) and any software and/or firmware (“code”) which may configure the hardware, be executed by the hardware, and or otherwise be associated with the hardware. As used herein, for example, a particular processor and memory may comprise a first “circuit” when executing a first one or more lines of code and may comprise a second “circuit” when executing a second one or more lines of code. As used herein, “and/or” means any one or more of the items in the list joined by “and/or”. As an example, “x and/or y” means any element of the three-element set {(x), (y), (x, y)}. As another example, “x, y, and/or z” means any element of the seven-element set {(x), (y), (z), (x, y), (x, z), (y, z), (x, y, z)}. As used herein, the term “exemplary” means serving as a non-limiting example, instance, or illustration. As used herein, the terms “e.g.,” and “for example” set off lists of one or more non-limiting examples, instances, or illustrations. As used herein, circuitry is “operable” to perform a function whenever the circuitry comprises the necessary hardware and code (if any is necessary) to perform the function, regardless of whether performance of the function is disabled or not enabled (e.g., by a user-configurable setting, factory trim, etc.). As used herein, the term “based on” means “based at least in part on.” For example, “x based on y” means that “x” is based at least in part on “y” (and may also be based on z, for example).

While the present method and/or system has been described with reference to certain implementations, it will be understood by those skilled in the art that various changes may be made and equivalents may be substituted without departing from the scope of the present method and/or system. In addition, many modifications may be made to adapt a particular situation or material to the teachings of the present disclosure without departing from its scope. Therefore, it is intended that the present method and/or system not be limited to the particular implementations disclosed, but that the present method and/or system will include all implementations falling within the scope of the appended claims.

What is claimed is:

1. A system, the system comprising:
a plurality of optical fibres; and
a plurality of photodiodes, wherein:
a first optical fibre of the plurality of optical fibres is parallel to a second optical fibre of plurality of optical fibres,
the first optical fibre and the second optical fibre are each cleaved at an angle such that a first primary optical path exiting the first optical fibre is not parallel to a second primary optical path exiting the second optical fibre, and
a first photodiode of the plurality of photodiodes is positioned according to the first primary optical path exiting the first optical fibre, and
a second photodiode of the plurality of photodiodes is positioned according to the second primary optical path exiting the second optical fibre.

2. The system of claim 1, wherein:
the first optical fibre and the second optical fibre are separated by pre-defined spacing.

3. The system of claim 1, wherein:
an end of the first optical fibre is offset from an end of the second optical fibre.

4. The system of claim 1, wherein:
an end of the first optical fibre is offset by reasonable distance from an end of the second optical fibre.

5. The system of claim 1, wherein:
an angle between an axis of the first optical fibre and the first primary optical path exiting the first optical fibre is defined to achieve maximum responsivity, high return loss and high isolation.

6. The system of claim 1, wherein:
a distance between the first optical fibre and the first photodiode is pre-defined for maximum responsivity and high return loss.

7. The system of claim 1, wherein:
the plurality of photodiodes comprise InGaAs PIN diodes.

8. The system of claim 1, wherein:
a multi-port receiver comprises the plurality of photodiodes, and
the plurality of optical fibres enter the multi-port receiver from two sides.

9. The system of claim 1, wherein:
a multi-port receiver comprises the plurality of photodiodes, and
each of the plurality of photodiodes are located on a step of a stair step arrangement.

10. The system of claim 1, wherein:
a multi-port receiver comprises the plurality of photodiodes, and
the plurality of optical fibres that enter the multi-port receiver are arranged in two dimensions as rows and columns of optical fibres.

11. A system, the system comprising:
a plurality of optical fibres; and
a plurality of photodiodes, wherein:
a first optical fibre of the plurality of optical fibres is parallel to a second optical fibre of plurality of optical fibres,
the first optical fibre and the second optical fibre are each cleaved at an angle such that a first primary optical path exiting the first optical fibre is not parallel to a second primary optical path exiting the second optical fibre, and
an end of the first optical fibre is offset from an end of the second optical fibre.

12. The system of claim 11, wherein:
the first optical fibre and the second optical fibre are separated by pre-defined spacing.

13. The system of claim 11, wherein:
a first photodiode of the plurality of photodiodes is positioned according to the first primary optical path exiting the first optical fibre, and
a second photodiode of the plurality of photodiodes is positioned according to the second primary optical path exiting the second optical fibre.

14. The system of claim 11, wherein:
an end of the first optical fibre is offset by reasonable distance from an end of the second optical fibre.

15. The system of claim 11, wherein:
an angle between an axis of the first optical fibre and the first primary optical path exiting the first optical fibre is pre-defined for maximum responsivity and high return loss.

16. The system of claim 11, wherein:
a distance between the first optical fibre and the first photodiode is pre-defined for maximum responsivity and high return loss.

17. The system of claim 11, wherein:
the plurality of photodiodes comprise InGaAs PIN diodes.

18. The system of claim 11, wherein:
a multi-port receiver comprises the plurality of photodiodes, and
the plurality of optical fibres enter the multi-port receiver from two sides.

19. The system of claim 11, wherein:
a multi-port receiver comprises the plurality of photodiodes, and
each of the plurality of photodiodes are located on a step of a stair step arrangement.

20. The system of claim 11, wherein:
a multi-port receiver comprises the plurality of photodiodes, and
the plurality of optical fibres that enter the multi-port receiver are arranged in two dimensions as rows and columns of optical fibres.
